(19) United States
(12) Patent Application Publication
(10) Pub. No.: US 2009/0279361 A1
(43) Pub. Date: Nov. 12, 2009

(54) Addressable Memory Array

(75) Inventor: Bohumil Lojek, Colorado Springs, CO (US)

Correspondence Address: FISH & RICHARDSON P.C., PO BOX 1022, MINNEAPOLIS, MN, 55440-1022, US

(73) Assignee: ATMEL CORPORATION, San Jose, CA (US)

(21) Appl. No.: 12/115,952

(22) Filed: May 6, 2008

(51) Int. Cl. G11C 16/06; H01L 21/336

(52) U.S. Cl. 365/185.18; 438/257; 257/E21.409

(57) ABSTRACT

This document discloses non-volatile memory cells and methods of manufacturing the same. The memory arrays are byte, word, and/or page addressable without using a byte select transistor. The byte select transistor is eliminated by using the well, memory transistor control gates, and select transistor gates to selectively program a byte, word, or page.

### BACKGROUND

This specification relates to non-volatile memory arrays.

Electronic devices are being developed that offer more capabilities, utilize less power and can be manufactured in small packages. For example, portable computing devices have evolved into comprehensive data devices that integrate the features of phones, personal digital assistants (PDAs) and computers. As the capabilities of these devices increase, so do their memory and power requirements. The increasing memory requirements of electronic devices, coupled with shrinking power budgets and packaging dimensions, require memory devices that offer more storage, with lower power consumption, and smaller physical dimensions.

An electrically erasable programmable read only memory (EEPROM) cell is a particular non-volatile memory cell. EEPROM scaling is dependent on the number of transistors that are used to create the memory cell. Some EEPROM memory cells use a byte select transistor to provide byte addressability. However, use of a byte select transistor increases the number of transistors needed to construct the memory cell. Accordingly, use of a byte select transistor limits device density.

### SUMMARY

This document discloses non-volatile memory arrays and methods of manufacturing the same. The memory arrays are byte, word, and/or page addressable without use of a byte select transistor. The byte select transistor is eliminated by using transistor wells, memory transistor control gates, and select transistor gates to selectively program a byte, word, or page.

Particular implementations of the subject matter described in this specification can be implemented so as to realize one or more of the following optional advantages. The need for fabrication and use of a byte select transistor is eliminated. The dimensions of the memory array can be reduced as compared to memory arrays that include byte select transistors. The spacing of the active region across the memory array can be more uniform. Each byte and/or page column can include a separate source.

The details of one or more embodiments of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 is a partial schematic of an example EEPROM memory array.

FIG. 2 is a partial schematic of an example memory array biased to perform an erase operation.

FIG. 3 is a partial schematic of an example memory array biased to perform a write operation.

FIG. 4 is a partial schematic of an example memory array biased to perform a read operation.

FIG. 5 is a flow chart of an example process of manufacturing a byte/page selectable memory array.

Like reference numbers and designations in the various drawings indicate like elements.

### DETAILED DESCRIPTION

### I. Byte/Page Addressable Memory Array

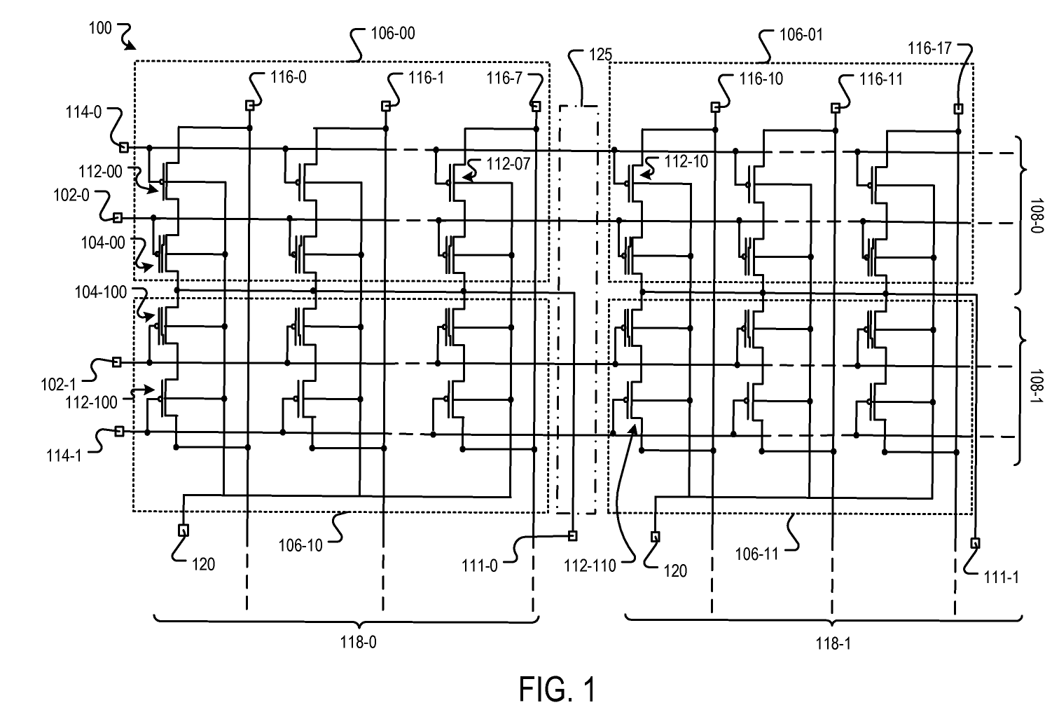

FIG. 1 is a partial schematic of an example EEPROM memory array 100. The example memory array 100 can include n word lines 102, of which the first two word lines 102-0, 102-1 are shown. The word lines 102 are arranged according to a matrix architecture, e.g., in parallel. Each word line 102 is respectively connected to corresponding control gates of memory transistors 104 that define bytes 106 of a word 108, of which the first two bytes 106-00, 106-01 of word 108-0 and the first two bytes 106-10, 106-11 of byte 108-1 are shown. The memory transistors 104 that define a byte 106 are connected to a common source 111, of which the first two common sources 111-0, 111-1 are shown.

Pages of the memory array 100 can be defined, for example, by words 108. For example, the words 108-0 or 108-1 can each individually define a page. Alternatively, the words 108-0 and 108-1 can together define a page. The page size can be determined according to the application.

In some implementations, the memory transistors 104 can be MOSFET floating gate transistors. Other types of memory transistors, however, can also be used.

Each memory transistor 104 has a drain that is connected to a corresponding select transistor 112. The select transistors 112 that are connected to memory transistors 104 on a common word line 102 have gates that are connected to a common select line 114, of which the first two select lines 114-0, 114-1 are shown. For example, the select transistors 112-0-112-7 that are connected to select line 114-0 are also connected to the memory transistors 104-0-104-7 that, in turn, are connected to word line 102-0. In some implementations, the bytes 106 that define a word 108 are distributed across a continuous word line 104 and a continuous select line 114.

A select transistor 112 from each select line 114 is connected to a common bit line 116, of which three bit lines 116-0, 116-1, 116-7 are shown for byte 106-00 and three bit lines 116-10, 116-11, 116-17 are shown for byte 106-01. The bit lines 116 can be connected to drains of the respective select transistors 112. In some implementations, a byte column 118 can be defined by the bytes 106 that correspond to a common group of bit lines 116. For example, the bytes 106-00 and 106-10 that correspond to the bit lines 116-0-116-7 define a byte column 118-0. In turn, the memory transistors 104 that define each byte column 118 can be connected to a common source 111.

In some implementations, the memory transistors 104 and/or select transistors 112 can be MOSFET floating gate structures. When a floating gate structure is used for the select transistors 112, the respective control gates and the floating gates can be connected so that the select transistors 112 operate as single gate transistors. Using a floating gate structure for the select transistors 112 allows the memory cell transistor gates to be fabricated using one mask. Other types of select transistors can be used (e.g., single gate structures).

The memory array 100 can be implemented over a well that is defined in a semiconductor substrate. In some implementations, a well line 120 can be attached to the well so that the well can be used as a biasing element to facilitate write operations and erase operations for the memory transistors 104. In some implementations, the well can be implemented as a triple well. The triple well can be continuous, for example, across the entire memory array 100, thereby resulting in a common well across all memory transistors 104.

The architecture of the array 100 permits the elimination of byte select transistors between respective bytes, e.g., the elimination of byte select transistors in an area 125 between the respective bytes. Particular bytes or pages can be addressed (e.g., selected) by biasing the well line 120, select lines 114, word lines 102, bit lines 116, and sources 111 as described in Section II below. In some implementations, because a byte select transistor is not required, the required space between bytes 106 that define a word 108 (e.g., the space between byte 106-00 and byte 106-01) is reduced. In some implementations, applying biasing voltages to the well line 120, thereby using the well as a biasing element, facilitates the elimination of the byte select transistor.

### II. Memory Array Operation

Selective biasing of the well line 120, select lines 114, word lines 102, bit lines 116 and sources 111 can be used to perform erase operations, program operations, and read operations. Each of these operations and biasing conditions are described below.

i. Erase Operation

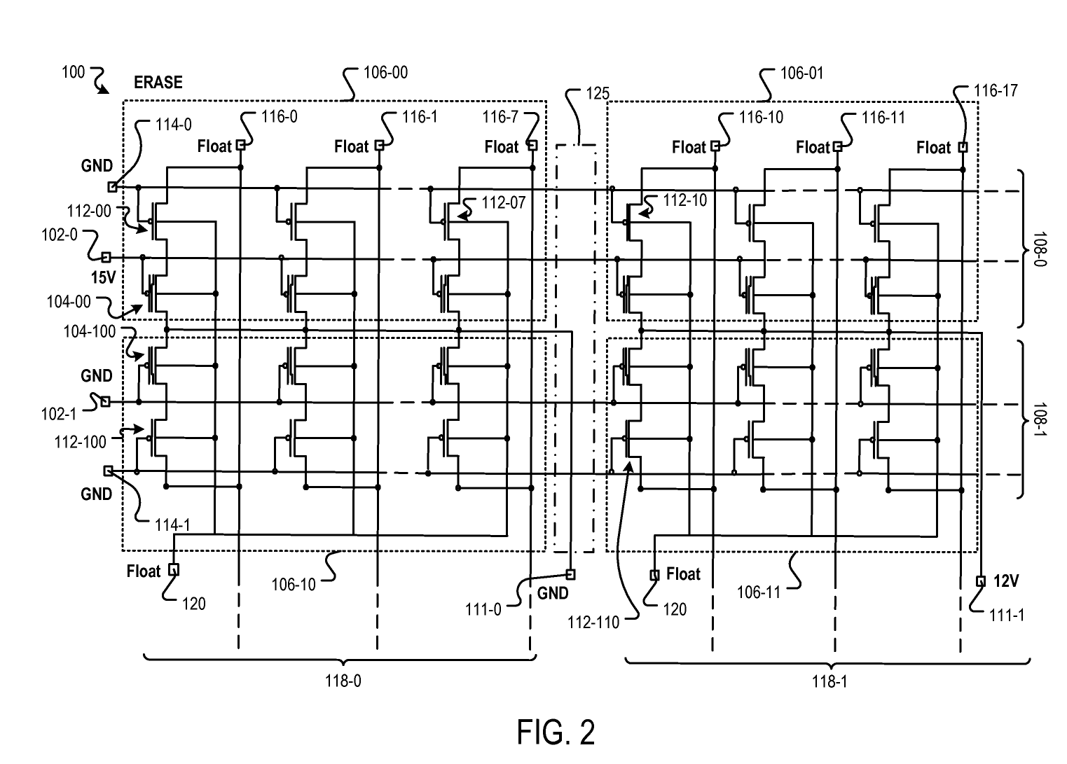

FIG. 2 is a partial schematic of an example memory array 100 biased to perform an erase operation. In some implementations, bytes, words, and/or pages of memory transistors 104 in the memory array 100 can be selectively erased. For example, when the voltages shown in FIG. 2 are applied to the array 100 all of the memory transistors 104-0-104-7 in the selected byte 106-00 are erased, while the memory transistors 104 that are in other bytes 106-01, 106-10, 106-11 are not erased. To erase the memory transistors 104-0-104-7 that define byte 106-00, a biasing voltage (e.g., 15V) is applied to the word line 102-0 that is connected to the gates of the memory transistors 104-0-104-7. Additionally, the source 111-0 that is connected to the memory transistors 104-0-104-7 is grounded. Meanwhile, the gate of each select line 114 is connected to ground while each bit line 116 is floating, thereby biasing each select transistor 112 off to prevent current flow through the select transistors 112.

Biasing the gates and sources of the memory transistors as described above results in gate to source voltages associated with the memory transistors 104-0-104-7 that is greater than a threshold voltage. Accordingly, the memory transistors 104-0-104-7 will be biased on, thereby allowing current to flow through the memory transistors 104-0-104-7. However, because the select transistors 112-00-112-07 are biased off, floating gates of the memory transistors 104-101-104-107 will discharge, thereby erasing the memory transistors 104-0-104-7. Similarly, if memory transistors that define a word 108 or a page are selected to be erased, the select lines 114, word lines 102 and sources 111 that are connected to the selected word 108 or page can be biased as described above.

In some implementations, the sources 111 that are connected to the bytes 106 can be used to address (e.g., select) individual bytes. For example, continuing with the example above, the byte 106-01 can be selectively erased by biasing the source 111-1. If the source 111-1 is grounded, then the memory transistors 104 that define byte 106-01 will be erased in a similar manner as the memory transistors 104 that define byte 106-00. However, if the source 111-1 is biased with a non-select voltage (e.g., 10-13V), the gate to source voltages associated with the memory transistors 104-10-104-17 will not exceed the threshold voltage. Accordingly, the memory transistors 104-10-104-17 will not be biased on, thereby preventing current flow from the floating gate of the memory transistors 104-0-104-17. Thus, bytes 106 that define a word 108 can be selectively erased based on the bias voltage that is applied to the source 111 of the memory transistors 104.

Similarly, bytes 106 that define a byte column 118 can be selectively erased based on whether a bias voltage is applied to the word line 102 that is connected to the byte 106. Continuing with the example presented above, the byte 106-10 can be selectively erased by applying a biasing voltage (e.g., 15V) to the word line 102-1. Applying the bias voltage to the word line 102-1 results in biasing memory transistors 104-101-104-107 that define the byte 106-10 to conduct current. In turn, the floating gates of the memory transistors 104-101-104-107 will discharge, thereby erasing the memory transistors 104-101-104-107.

In some implementations, selectively erasing a word 108 can be performed by biasing each of the one or more bytes 106 that define the word 108 in a manner similar to that described with reference to byte 106-00. For example, word 108-0 can be erased by grounding the source 111 of each byte column 118, while applying the voltages to the word lines 102 and select lines 114, as shown in FIG. 1. Additionally, a page of memory transistors 104 can be selectively erased by biasing each of the one or more words 108 that define the page as described with reference to word 108-0.

ii. Program Operation

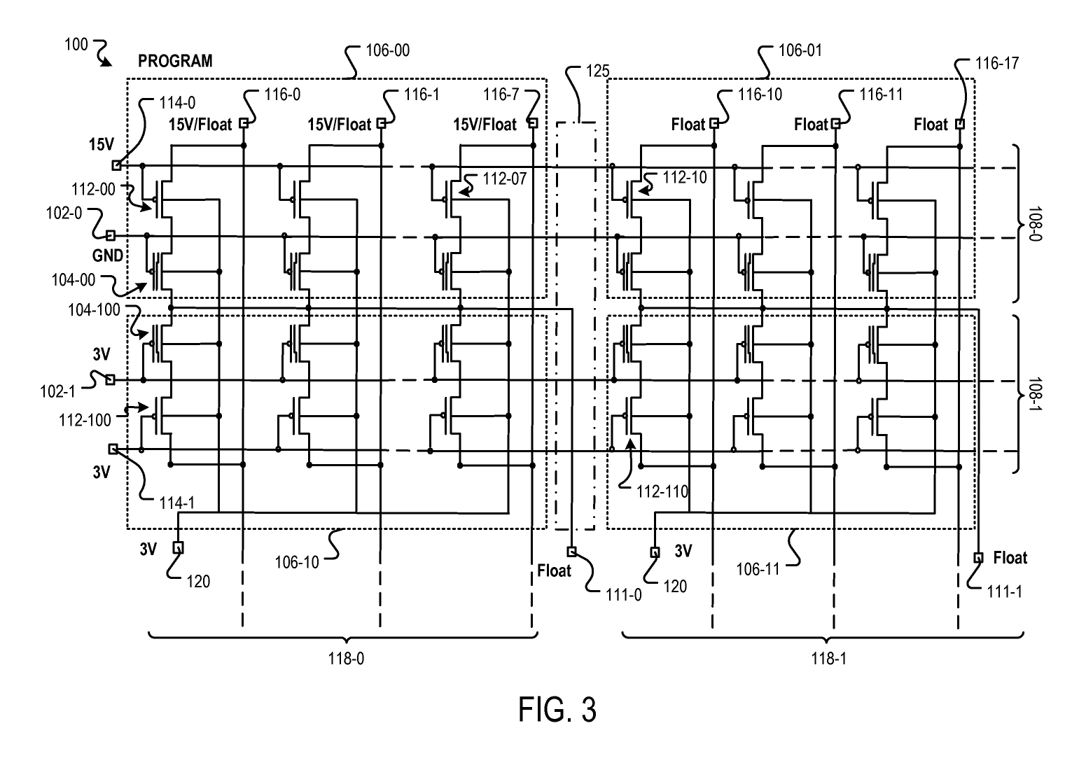

FIG. 3 is a partial schematic of an example memory array 100 biased to perform a program operation. In some implementations, bytes, words, and/or pages of memory transistors 104 in the memory array 100 can be selectively programmed. For example, when the voltages shown in FIG. 3 are applied to the array 100, each of the memory transistors 104-0-104-7 in the selected byte 106-00 can be selectively programmed, while the memory transistors 104 that are in other bytes 106-01, 106-10, 106-11 are not programmed.

To program the memory transistors 104-0-104-7 that define byte 106-00, a biasing voltage (e.g., 15V) is applied to the select line 114-0 that is connected to the gates of the select transistors 112-0-112-7 to be programmed. Additionally, the word line 102-0 that is connected to the gates of the memory transistors 104-0-104-7 in the selected byte 106-00 is connected to ground. Meanwhile, a well program voltage (e.g., 3V) is applied to the well line 120-0 as well as the select lines 113 and word lines 102 that are connected to unselected bytes 106. In turn, the memory transistors 104 that define unselected bytes 106 will not be biased on, and therefore, will not be programmed. However, each memory transistor 104-0-104-7 that is in the selected byte 106-00 can be selectively programmed by applying a bias voltage (e.g., 15V) to the bit line 116-0-116-7 that corresponds to the memory transistor 104-0-104-7 to be programmed. All other bit lines 116 can be allowed to float.

Biasing the word lines 102, select lines 114, and well line 120 of the array 100 as described, results in byte 106-00 programming being dependent on the voltage that is applied to the bit lines 116-0-116-7, respectively. Applying a bias voltage (e.g., 15V) to a bit line 116 will cause the corresponding select transistor 112 to be biased on. In turn, the memory transistor 104 that is connected to the corresponding memory transistor 104 will be programmed because a sufficient gate to drain voltage (e.g., 18V) will be achieved. Accordingly, electrons will tunnel from the well to the floating gate of the memory transistor, charging the floating gate and thereby resulting in a programmed memory transistor.

However, if a bias voltage is not applied to a bit line, e.g., a bit line is floated, the corresponding select transistor 112 will not be biased on. In turn, the gate to drain voltage of the memory transistor 104 will not be sufficient to cause tunneling of electrons from the well to the floating gate. Accordingly, the memory transistor 104 will not be programmed.

For example, if a bias voltage (e.g., 15V) is applied to the bit line 116-0, select transistor 112-0 will be biased on. In turn, the memory cell 104-0 will have a gate to drain voltage (e.g., 18V) that is sufficient to cause tunneling of electrons from the well to the floating gate. In contrast, if the bit line 116-1 is floated, select transistor 112-1 will not be biased on. In turn, there will not be a difference in potential from the control gate of the memory transistor 104-1 and the well. Therefore, electrons will not tunnel to the floating gate of the memory transistor.

Similarly, if memory transistors 104 that define a word 108 or a page are selected to be programmed, the word lines 102, select lines 114, and well line 120 that are connected to the selected word or page can be biased as described above. In turn, a bias voltage can be selectively applied to the bit lines 116 to selectively program the memory transistors 104 that define the word or page, as described above.

In some implementations, biasing the transistors in the unselected bytes 106, as described above, can prevent the memory transistors 104 that define the unselected bytes from being programmed. Applying the well voltage to the gates of the select lines 114 in the unselected bytes prevents the select transistors 112 in the unselected bytes 106 from being biased on. Accordingly, current will not flow through the select transistors 114 in the unselected bytes 106, even if the unselected bytes are connected to bit lines 116 that are being subjected to a bias voltage. Additionally, applying the well voltage (e.g., 3V) to the gates of the memory transistors 104 that define the unselected bytes 106 prevents a voltage differential between the well and the control gates of the memory transistors 104. Therefore, no electrons will tunnel to, or from, the well to the floating gate of the memory transistors 104 in the unselected bytes 106.

In some implementations, a word 108 or a page can be selectively programmed. For example, to selectively program word 108-0, the bias voltages shown in FIG. 3 can be applied to the word lines 102, select lines 114, and well line 120. In turn, each memory transistor 104 that defines the word can selectively be programmed by applying a bias voltage (e.g., 15 V) to the memory transistors to be programmed. Similarly, to selectively program a page, each of the word lines 102 and select lines 114 for the words 108 that define the page to be programmed can be biased in a manner similar to word line 102-0 and select line 114-0, as shown in FIG. 3.

iii. Read Operation

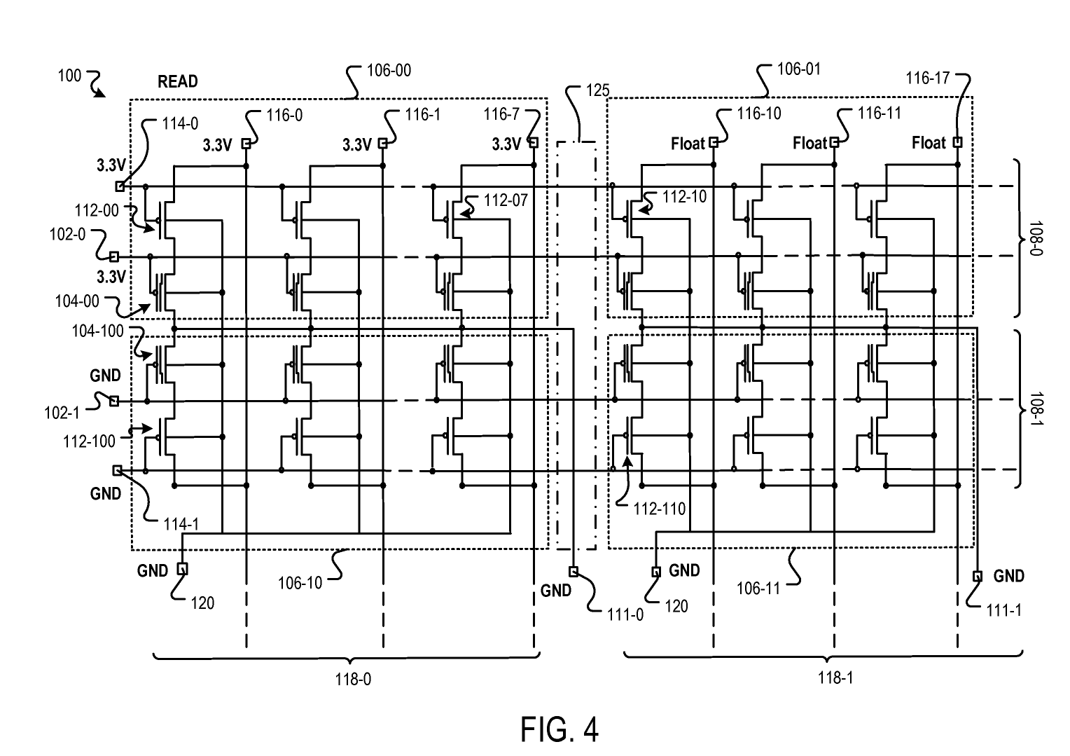

FIG. 4 is a partial schematic of an example memory array 100 biased to perform a read operation. In some implementations, a read voltage (e.g., 1.8V, 3V, etc.) can be applied to a word line 102 and select line 114 that is connected to the byte 106 or word 108 to be read, while the corresponding sources 111 and well lines 120 are grounded. Meanwhile, the read voltage can also be applied to the bit lines 116 of the select transistors 112 that correspond to the memory transistors 104 that define the byte 106 or word 108 to be read. In turn, the current on each bit line 116 can be sensed to determine whether the corresponding memory transistor 104 represents logic 1 or logic 0. Bytes 106 can remain unselected if either the word line 102 and select line 114 remain unbiased or the bit lines 116 connected to the byte 106 remain unbiased.

For example, byte 106-00 can be selected to be read by applying 3.3V to select line 114-0, word line 102-0, and bit lines 116-0-116-7. Applying the 3.3V to these elements of the array 100 will bias the select transistors 112-0-112-7 and memory transistors 104-0-104-7 to allow current to flow. In turn the current can be sensed on each bit line 116-0-116-7 by a current sensor to determine if each corresponding memory transistor 104-0-104-7 represents a logic 1 or a logic 0.

In this configuration, byte 106-01 can remain unselected by applying a reference voltage (e.g., ground) to bit lines 116-10-116-17. By grounding bit lines 116-10-116-17 the current detected in the bit lines 116-10-116-17 will not be sufficient to be sensed as logic 0 or logic 1. Bytes 106-10 and 106-11 can remain unselected by grounding word line 102-1 and select line 114-1, thereby preventing current from flowing through the corresponding memory transistors 104-100-104-117.

### III. Example Process Flow

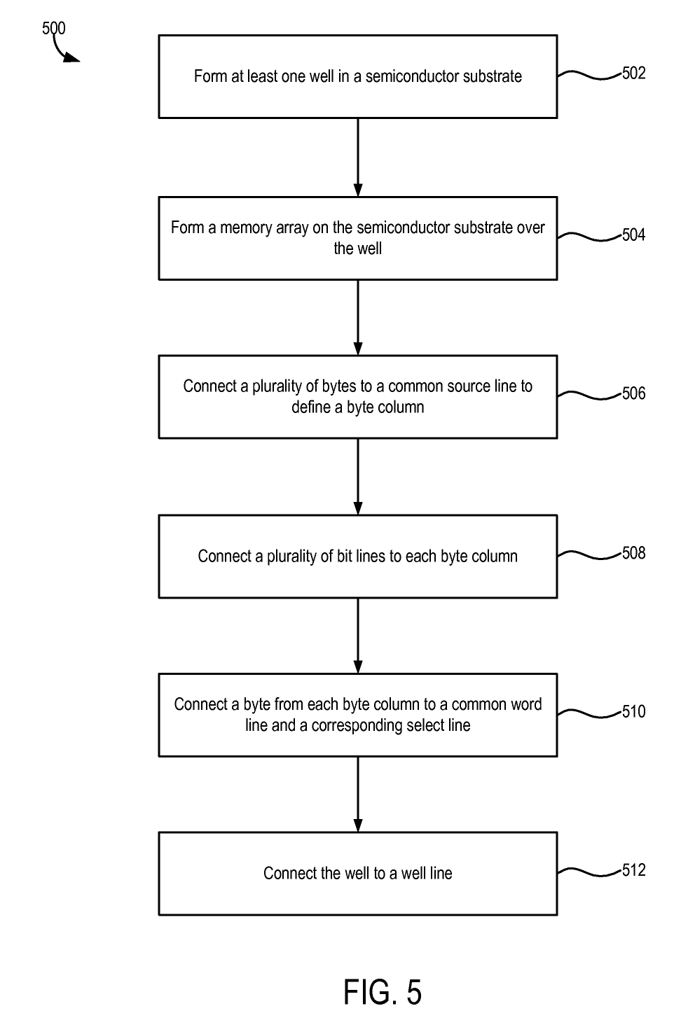

FIG. 5 is a flow chart illustrating an example process 500 of manufacturing a byte/page addressable memory array. One example byte/page addressable memory array can be the memory array of FIGS. 1-4. The process 500 can be implemented with conventional semiconductor fabrication equipment and processes.

Stage 502 forms at least one well in a semiconductor substrate. In some implementations, the well can be a triple well. The well can be continuous under the memory array.

Stage 504 forms a memory array on the semiconductor substrate over the well. In some implementations, the memory array can define bytes of memory. The memory array can be formed, for example, from a plurality of memory transistors that are each connected to a corresponding select transistor. In some implementations, the memory transistors and select transistors can be formed having floating gate structures. The select transistors can have the floating gate and control gate electrically connected. Connecting the control gate and floating gate facilitates use of the select transistor as a single gate device.

Stage 506 connects a plurality of bytes to a common source line to define a byte column. In some implementations, the common source line can be connected to the source of each memory transistor in each byte. The memory transistor sources can be defined, for example, by a p-region formed in the semiconductor substrate.

Stage 508 connects a plurality of bit lines to each byte column. In some implementations, each bit line can be connected to a drain of one select transistor from each byte in the byte column. The drains of the select transistors can be defined, for example, by a p-region formed in the semiconductor substrate.

Stage 510 connects a byte from each byte column to a common word line and a corresponding common select line. In some implementations, the common word line can be connected to a gate that is continuous across each memory transistor in each byte that is connected to the common word line. In some implementations, the word line can be connected to the floating gate of the memory transistors. Similarly, the select line can be connected, for example, to a gate that is continuous across each select transistor that is connected to the common select line.

Stage 512 connects the well to a well line. In some implementations, the well line can be configured to receive a connection from a biasing source to selectively bias the well.

While this document contains many specific implementation details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while process steps are depicted in the drawings in a particular order, this should not be understood as requiring that such process steps be performed in the particular order shown or in sequential order, or that all illustrated process steps be performed, to achieve desirable results.

Particular embodiments of the subject matter described in this specification have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results.

What is claimed is:

1. A memory device, comprising:
a plurality of memory transistors connected to a word line and grouped to define bytes;
a plurality of select transistors, each select transistor connected to a corresponding memory transistor;
a select line connected to the select transistors;
a plurality of bit lines, each bit line connected to a select transistor;
a plurality of source lines corresponding to the groups of memory transistors defining bytes, each source line connected to the sources of each memory transistor in the corresponding group; and
a well line connected to a well that is common to each memory transistor, wherein the well line is configured to receive biasing voltages for selectively biasing the well.

2. The memory array of claim 1, wherein the plurality of memory transistors are floating gate transistors.

3. The memory array of claim 1, wherein the plurality of select transistors have a floating gate that is connected to a control gate.

4. The memory array of claim 1, wherein the well line receives a connection from a biasing source to selectively bias the well in response to a plurality of memory operations.

5. The memory array of claim 4, wherein the well is biased to a well program voltage during a program operation.

6. The memory array of claim 5, wherein the program operation is performed on at least one byte of grouped memory transistors.

7. The memory array of claim 1, wherein the well is a triple well.

8. The memory array of claim 1, wherein each source line is configured to be connected to a biasing source to selectively bias the source during an erase operation.

9. A method, comprising:
forming a well in a semiconductor substrate,
forming a memory array on the semiconductor substrate over the well, wherein the memory array defines bytes of memory,
connecting a plurality of the bytes to a common source line to define a byte column;
connecting a plurality of bit lines to each byte column;
connecting a byte from each byte column to a common word line and a corresponding select line; and
connecting the well to a well line, wherein the well line is configured to receive biasing voltages from a biasing source to selectively bias the well.

10. The method of claim 9, wherein the well comprises a triple well.

11. The method of claim 9, wherein forming a memory array on the semiconductor substrate comprises:
forming a plurality of memory transistors and select transistors on a portion of the semiconductor substrate; and
connecting each memory transistor to a corresponding select transistor.

12. The method of claim 11, wherein connecting a plurality of bytes to a common source line comprises connecting a source from each memory transistor in each of the plurality of bytes to the common source line.

13. The method of claim 11, wherein connecting a byte from each byte column to a common word line and a corresponding select line comprises:
connecting a word line to a gate that is common to memory transistors that define a byte; and
connecting a select line to select transistors that are connected to memory transistors having a common word line.

14. The method of claim 9, wherein a byte column comprises one or more bytes that are connected to common bit lines.

15. A memory device, comprising:
a plurality of word lines;
a plurality of memory transistors connected to each word line;
a plurality of select transistors, each select transistor connected to a corresponding memory transistor;
a plurality of select lines, each select line connected to select transistors that are connected to memory transistors that define a byte;
a plurality of bit lines, each bit line connected to a select transistor on each select line;
a plurality of source lines, each source line connected to sources of the memory transistors that define the byte; and
a well line connected to a well that is common to each memory transistor, wherein the well line is configured to receive biasing voltages for selectively biasing the well.

16. The memory array of claim 15, wherein the plurality of memory transistors are floating gate transistors.

17. The memory array of claim 15, wherein the plurality of select transistors have a floating gate that is connected to a control gate.

18. The memory array of claim 15, wherein the well line is configured to receive a connection from a biasing source to selectively bias the well.

19. The memory array of claim 18, wherein the well is biased during a program operation.

20. The memory array of claim 19, wherein the program operation is performed on at least one byte of memory transistors.

21. The memory array of claim 15, wherein each source line is configured to be connected to a biasing source to selectively bias the source during an erase operation.

22. The memory array of claim 15, wherein bytes connected to a common word line are connected adjacent to each other.

23. A memory device, comprising:
a semiconductor substrate having a well defined therein;
a memory array formed on the semiconductor substrate, wherein the memory array defines bytes of memory, and wherein bytes of memory that are located over a the well define a byte column;
a well line connected to the well, wherein the well line is configured to be connected to a biasing source for selectively biasing the well during operation of the memory device; and
a source line connected to each byte column.

24. The memory device of claim 23, wherein the memory array comprises:
a plurality of memory cells, wherein the plurality of memory cells define bytes, and wherein the bytes define words;
a plurality of word lines, each word line connected to a corresponding word;
a plurality of select lines, each select line connected to a corresponding word; and
a plurality of bit lines, each bit line connected to a corresponding memory cell in a byte.
